(19) United States
(12) Patent Application Publication
(10) Pub. No.: US 2025/0276335 A1
(43) Pub. Date: Sep. 4, 2025

(54) BONDED SHOWERHEAD ASSEMBLY AND METHOD FOR USING THE SAME

(71) Applicant: Applied Materials, Inc., Santa Clara, CA (US)

(72) Inventors: Michael A. STEARNS, San Jose, CA (US); Carlaton WONG, Sunnyvale, CA (US); Reyn WAKABAYASHI, San Jose, CA (US)

(21) Appl. No.: 18/592,047

(22) Filed: Feb. 29, 2024

(51) Int. Cl. B05B 1/24; B05B 1/18; C23C 16/455

(52) U.S. Cl. CPC B05B 1/24; B05B 1/18; C23C 16/45565

(57) ABSTRACT

The present disclosure generally relate to a processing chamber comprising a showerhead assembly. The showerhead assembly comprises a heat transfer plate having a first side and a second side, the heat transfer plate having cooling channels formed adjacent the first side of the heat transfer plate and a heater formed in the second side of the heat transfer plate, a showerhead plate having a first side coupled to the second side the heat transfer plate, a first gas passageway extending through the heat transfer plate to the showerhead plate, and a gas distribution plate (GDP) bonded to a second side of the showerhead plate, the GDP having a first plurality of holes formed therethrough, first ends of the first plurality of holes open to the showerhead plate. The showerhead plate comprises a metal backing and a plurality of anodized gas paths extending within the metal backing.

### BACKGROUND

### Field

Embodiments of the present disclosure generally relate to showerhead assembly, a processing chamber having a showerhead assembly, and a method for using the showerhead assembly.

### Description of the Related Art

Semiconductor substrates are processed for a wide variety of applications, including the fabrication of integrated devices and micro devices. One such processing device is an etch processing chamber. During processing, the substrate is positioned on a substrate support within the etch processing chamber. Gas is introduced into the etch chamber via a showerhead assembly and ignited into a plasma for etching a substrate.

However, repeated exposure of the gas can cause components of the showerhead assembly to degrade or corrode overtime. When components of the showerhead assembly breakdown, the processing chamber may no longer be functional until the corroded components can be replaced with new components. If the corroded components are unable to be replaced due to the complexity of the showerhead assembly, the processing chamber may be unusable.

Therefore, a need exists for improved showerhead assembly.

### SUMMARY

The present disclosure generally relates to showerhead assembly, a processing chamber having the showerhead assembly, and a method for using the showerhead assembly. In one example, a showerhead assembly includes a heat transfer plate having a first side and a second side, the heat transfer plate having cooling channels formed adjacent the first side of the heat transfer plate and a heater formed in the second side of the heat transfer plate, a showerhead plate having a first side coupled to the second side the heat transfer plate, a first gas passageway extending through the heat transfer plate to the showerhead plate, and a gas distribution plate (GDP) bonded to a second side of the showerhead plate, the GSP having a first plurality of holes formed therethrough, first ends of the first plurality of holes open to the showerhead plate.

In another example, a showerhead assembly includes a heat transfer plate having a first side coupled to a second side by a sidewall, the heat transfer plate having cooling channels formed adjacent the first side of the heat transfer plate and a heater disposed in a heater receiving channel formed in the second side of the heat transfer plate, a showerhead plate having a first side coupled to the second side the heat transfer plate, and a gas distribution plate bonded to a second side of the showerhead plate, the gas distribution plate having a first plurality of holes formed therethrough, first ends of the first plurality of holes open to the showerhead plate.

In another example, a showerhead assembly includes a heat transfer plate having a first side coupled to a second side by a sidewall, the heat transfer plate having cooling channels formed adjacent the first side of the heat transfer plate and a heater disposed in a heater receiving channel formed in the second side of the heat transfer plate, a showerhead plate having a first side coupled to the second side the heat transfer plate, wherein the showerhead plate comprises a plurality of anodized gas channels in a second side of the showerhead plate, a first gas passageway extending through the heat transfer plate to the plurality of anodized gas channels of the showerhead plate, and a gas distribution plate bonded to a second side of the showerhead plate, the gas distribution plate having a first plurality of holes formed therethrough, first ends of the first plurality of holes open to the plurality of anodized gas channels formed in the showerhead plate.

In yet another example, a processing chamber is provided that includes a chamber body having an internal volume, a substrate support disposed in the internal volume, a lid disposed on the chamber body and enclosing the internal volume, a heat transfer plate having a first side coupled to a second side by a sidewall, the heat transfer plate having cooling channels formed adjacent the first side of the heat transfer plate and a heater disposed in a heater receiving channel formed in the second side of the heat transfer plate, a showerhead plate having a first side coupled to the second side the heat transfer plate, wherein the showerhead plate comprises a plurality of gas channels in a second side of the showerhead plate, and a gas distribution plate bonded to a second side of the showerhead plate, the gas distribution plate having a first plurality of holes formed therethrough, first ends of the first plurality of holes open to the plurality of gas channels formed in the showerhead plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional view of a processing chamber according to one or more embodiments of the disclosure.

FIG. 2 illustrates a conventional showerhead assembly.

FIG. 3A illustrates a showerhead assembly, according to one embodiment.

FIG. 3B illustrates a showerhead plate of the showerhead assembly of FIG. 3A.

FIG. 3C illustrates anodized components of the showerhead assembly of FIG. 3A.

FIG. 4A illustrates a bottom view of the showerhead plate of the showerhead assembly of FIGS. 3A-3C comprising two zones, according to one embodiment.

FIG. 4B illustrates a bottom view of the showerhead plate of the

showerhead assembly of FIGS. 3A-3C comprising three zones, according to another embodiment.

FIG. 5 illustrates the pressure sensor and pressure sensing channel of the showerhead assembly of FIGS. 3A-3C, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to showerhead assembly, a processing chamber having a showerhead assembly, and a method for using the showerhead assembly. The showerhead assembly includes a heat transfer plate having a first side and a second side, the heat transfer plate having cooling channels formed adjacent the first side of the heat transfer plate and a heater formed in the second side of the heat transfer plate, a showerhead plate having a first side coupled to the second side the heat transfer plate, a first gas passageway extending through the heat transfer plate to the showerhead plate, and a gas distribution plate (GDP) bonded to a second side of the showerhead plate, the GDP having a first plurality of holes formed therethrough, first ends of the first plurality of holes open to the showerhead plate.

Due to the showerhead plate 128 and the GDP 302 being coupled together by the adhesive and being distinct from the heat transfer plate 130 (i.e., not embedded within the heat transfer plate 130 like a conventional showerhead assembly), the showerhead plate 128 and the GDP 302 can be easily replaced when needed. Moreover, the showerhead plate 128 can be anodized, and the thin GDP 302 may have mechanically drilled holes, thus resulting in reduced costs when compared to a conventional showerhead assembly.

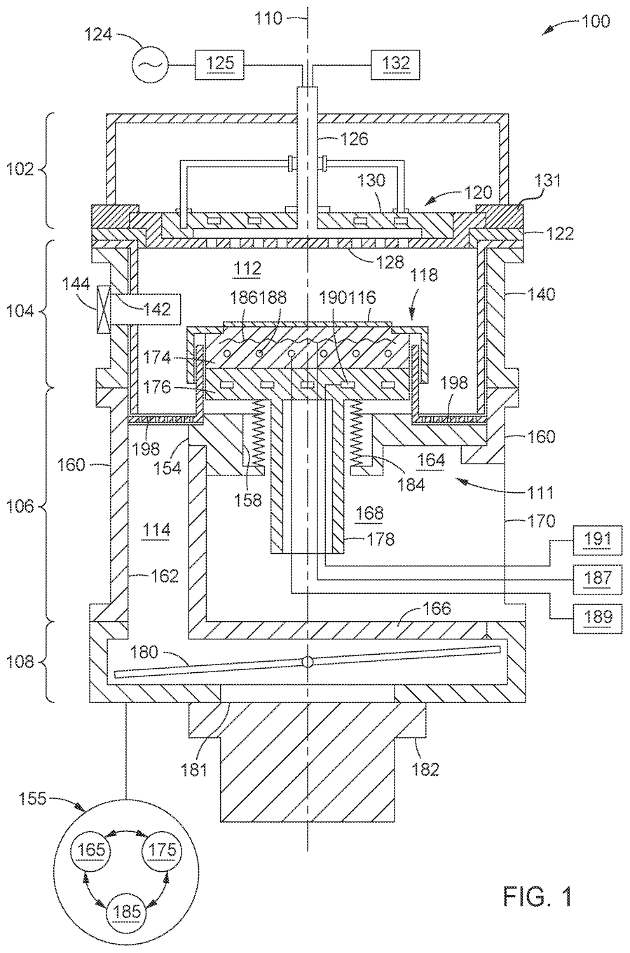

FIG. 1 is a schematic cross-sectional view of a processing chamber 100 according to one or more embodiments of the disclosure. The exemplary processing chamber 100 is suitable for patterning a material layer disposed on a substrate 116 in the processing chamber 100. The exemplary processing chamber 100 is suitable for performing a patterning process. The processing chamber 100 may be a plasma etch chamber, a plasma enhanced chemical vapor deposition chamber, a physical vapor deposition chamber, a plasma treatment chamber, an ion implantation chamber, or other suitable vacuum processing chamber.

The processing chamber 100 has a body 140. The body 140 generally has four external surfaces. The body 140 includes a source block 102, a process block 104, a flow block 106, and an exhaust block 108. It should be appreciated that the blocks may be one or more combination of blocks. For example, the exhaust block 108 is integral with and a part of the flow block 106 and made as a single unified body. The flow block 106 is part of a pumping port assembly 111 that includes a substrate support chassis 154. The source block 102, the process block 104 and the flow block 106 collectively enclose a process region 112. During operation, a substrate 116 may be positioned on a substrate support assembly 118 and exposed to a process environment, such as plasma generated in the process region 112. Exemplary process which may be performed in the processing chamber 100 may include etching, chemical vapor deposition, physical vapor deposition, implantation, plasma annealing, plasma treating, abatement, or other plasma processes. Vacuum may be maintained in the process region 112 by suction from an exhaust port 181 formed in the exhaust block 108 through one or more evacuation channels, i.e., evacuation channels 114, defined in the flow block 106.

The process region 112 and the evacuation channels 114 are substantially symmetrically about a central axis 110 to provide symmetrical electrical current, gas flow, thermal and pressure uniformity to establish uniform process conditions.

The source block 102 includes a showerhead assembly 120 (also referred to as an upper electrode or anode) may be isolated from and supported by the process block 104 by an isolator 122. Alternatively, the source block 102, may be electrically coupled to the process block 104, and grounded. A lid 131 is disposed on the isolator 122. The showerhead assembly 120 may include a showerhead plate 128 attached to a heat transfer plate 130. The showerhead assembly 120 may be connected to a gas source 132 through a gas inlet tube 126.

The gas source 132 may include one or more process gas sources and may additionally include inert gases, non-reactive gases, and reactive gases, if desired. Examples of process gases that may be provided by the gas source 132 include, but are not limited to, hydrocarbon containing gas including methane (CH₄), sulfur hexafluoride (SF₆), silicon chloride (SiCl₄), carbon tetrafluoride (CF₄), hydrogen bromide (HBr), hydrocarbon containing gas, argon gas (Ar), chlorine (Cl₂), nitrogen (N₂), helium (He) and oxygen gas (O₂). Additionally, process gasses may include nitrogen, chlorine, fluorine, oxygen and hydrogen containing gases such as BCl₃, C₂F₄, C₄F₈, C₄F₆, CHF₃, CH₂F₂, CH₃F, NF₃, NH₃, CO₂, SO₂, CO, N₂, NO₂, N₂O and H₂ among others.

The showerhead plate 128, the heat transfer plate 130, and the gas inlet tube 126 may be all fabricated from a radio frequency (RF) conductive material, such as aluminum or stainless steel. The showerhead assembly 120 may be coupled to a RF power source 124 via a match circuit 125 and the conductive gas inlet tube 126. The conductive gas inlet tube 126 may be coaxial with the central axis 110 of the processing chamber 100 so that both RF power and processing gases from the gas source 132 are symmetrically provided.

The process block 104 is disposed on the flow block 106. An RF gasket for grounding and an O-ring seal is disposed between the process block 104 and the flow block 106. Alternately, the process block 104 and flow block 106 are combined and made as a single unified body with no RF gasket for grounding and O-ring seal between them.

The process block 104 encloses the process region 112. The process block 104 may be fabricated from a conductive material resistive to processing environments, such as aluminum or stainless steel. The substrate support assembly 118 may be centrally disposed within the process block 104 and positioned to support the substrate 116 in the process region 112 symmetrically about the central axis 110.

A slit valve opening 142 may be formed through the process block 104 to allow passages of the substrate 116. A slit valve 144 may be disposed outside the process block 104 to selectively open and close the slit valve opening 142.

The process block 104 is disposed on the flow block 106. The flow block 106 provides flow paths between the process region 112 defined in the process block 104 and the exhaust block 108. The flow block 106 also provides an interface between the substrate support assembly 118 and the atmospheric environment exterior to the processing chamber 100.

The flow block 106 has through-holes 170 and evacuation channels 114. The through-holes 170 are maintained at atmospheric pressure and provide access to the substrate support assembly 118. The evacuation channels 114 are maintained at vacuum and provides a fluid path for removing gasses from the process region 112 to outside the processing chamber 100.

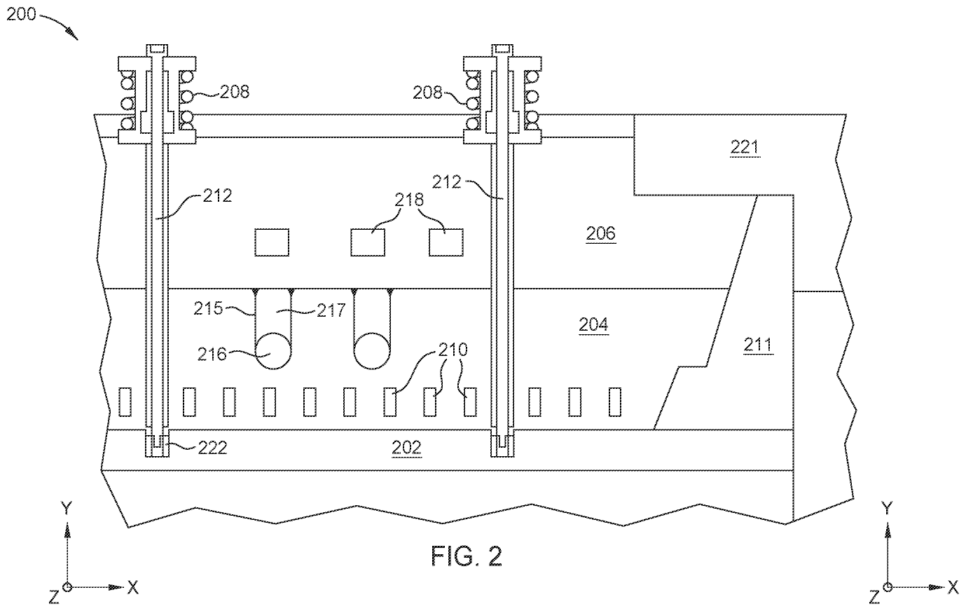

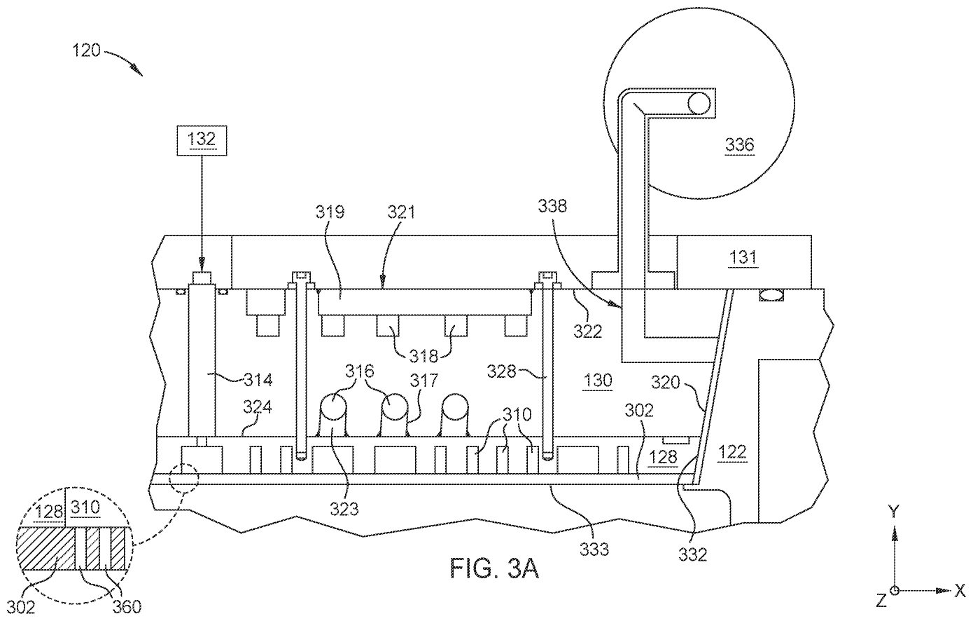

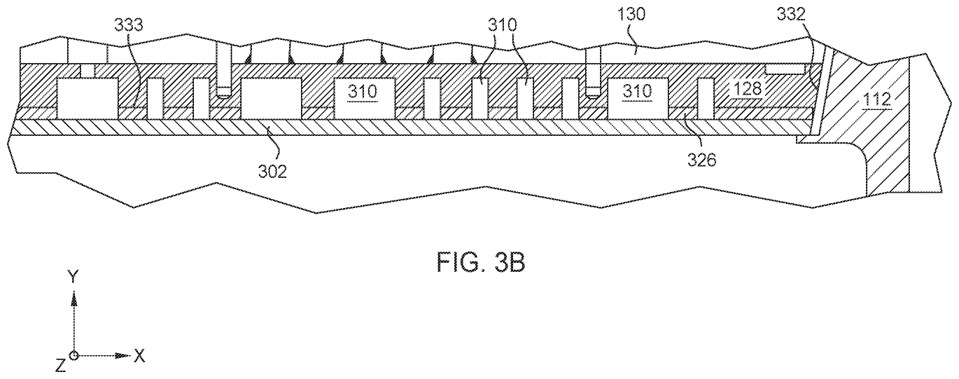

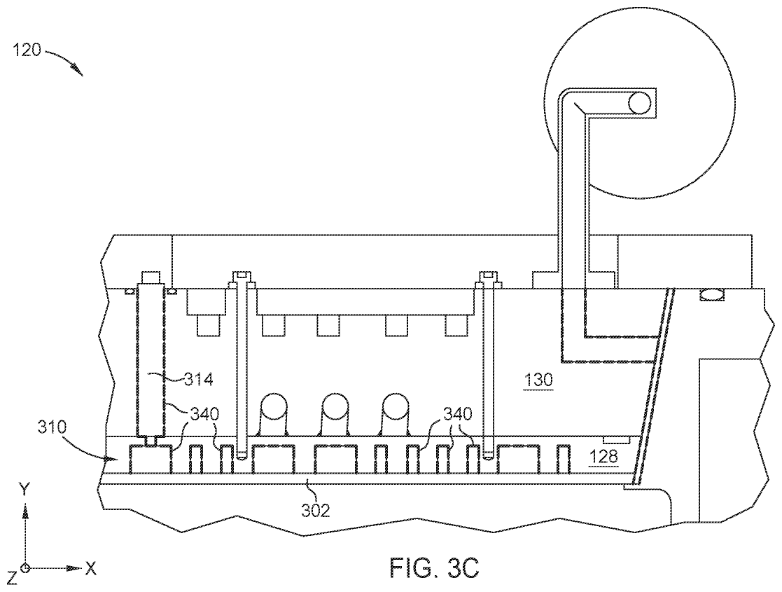

FIG. 2 illustrates a conventional showerhead assembly 200 that may be used to replace the showerhead assembly 120 in the processing chamber 100 described above. The conventional showerhead assembly 200 is provided for comparison to the novel showerhead assembly 120 as further detailed below with respect to FIGS. 3A-3C.

Continuing to refer to FIG. 2, the showerhead assembly 200 comprises a gas distribution plate (GDP) 202, a showerhead plate 204 disposed over the GDP 202, and a heat transfer plate 206 disposed over the showerhead plate 204. A lid 221 is disposed on the chamber body 140. In the case of a powered upper electrode, an isolator 211 is disposed between the lid 221 and showerhead assembly 200, adjacent to the sides of showerhead plate 204 and the heat transfer plate 206. The heat transfer plate 206 comprises a plurality of coolant channels 218 embedded therein. The showerhead plate 204 has one or more trenches or slots 215 formed therein. One or more heaters 216 and one or more plugs 217 are disposed within the one or more slots 215. The GDP 202 is tensioned against the showerhead plate 204 using a plurality of screws 212 and one or more springs 208. The screws 212 are thread into threaded inserts 222 inserted into the GDP 202. Thus, the GDP 202 must be thick enough to accommodate the inserts 222, which drives up the cost of the GDP 202 while also making the gas holes (not shown) formed through the GDP 202 more costly and time consuming to fabricate. The springs 208 are utilized to maintain good contact between the GDP 202 and showerhead plate 204 over a wide temperature range without having to overly torque the screws 212 and risking damage to the GDP 202. A plurality of o-rings (not shown) are disposed between the screws 212 and the showerhead plate 204 and/or heat transfer plate 206. The o-rings prevent gases from flowing out of the chamber and further protect the GDP 202. In one example, over 20 screws 212 and over 20 o-rings may be utilized.

A plurality of gas distribution channels 210 are embedded in the showerhead plate 204 above the GDP 202, wherein the gas distribution channels 210 are spaced from the GDP 202. The heat transfer plate 206 and the showerhead plate 204 may comprise aluminum, for example. The portion of the showerhead plate 204 disposed between the GDP 202 and the gas distribution channels 210 fails to distribute heat well during operation.

Because the coolant channels 218 and the gas distribution channels 210 are embedded within the heat transfer plate 206 and the showerhead plate 204, the coolant channels 218 and the gas distribution channels 210 are capped using diffusion bonding or welding when formed, making the processes available for protecting the interior surfaces of the gas distribution channels 210 from the process gases flowing therein very limited. For example, the atomic layer deposition techniques conventionally used to coat the interior surfaces of the gas distribution channels 210 within the showerhead plate 204 are very expensive and time consuming to apply, which significantly adds to the cost of the showerhead plate 204. Moreover, the diffusion bonding in and of itself is costly.

The GDP 202 comprises silicon, for example, and has a thickness in the y-direction of about 10 mm. The GDP 202 has a plurality of holes (not shown) disposed therethrough to distribute gas to a chamber disposed below. Due to the thickness of the GDP 202, the plurality of holes are typically laser drilled, which is costly and time consuming. Due to the various factors discussed (i.e., the springs, the diffusion bonding and ALD processes and laser drilled holes), the showerhead assembly 200 can be expensive to manufacture.

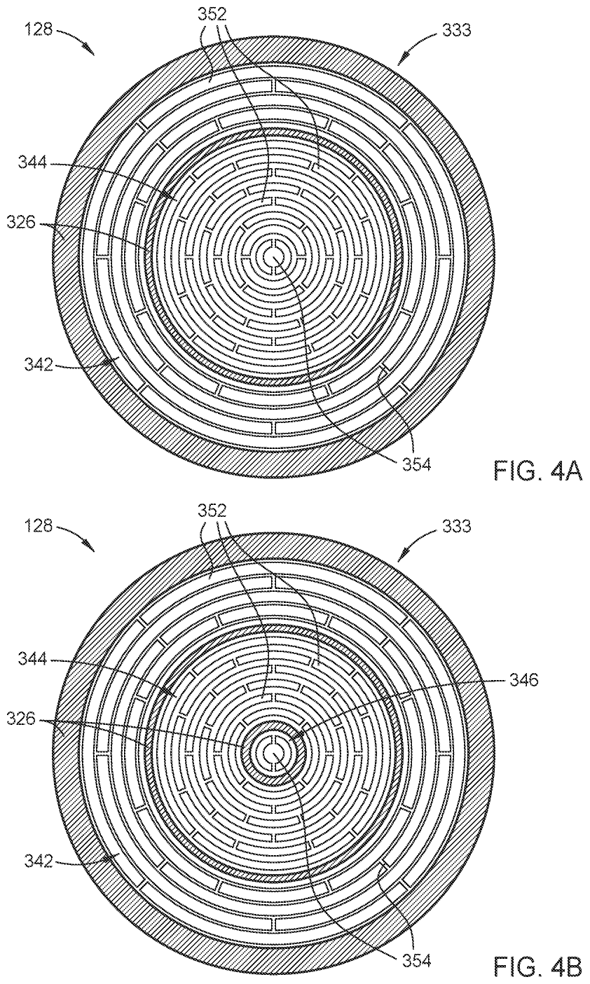

FIG. 3A illustrates a partial sectional view of the showerhead assembly 120, according to one embodiment. FIG. 3B illustrates a showerhead plate 128 of the showerhead assembly 120 of FIG. 3A. FIG. 3C illustrates anodized components of the showerhead assembly 120 of FIG. 3A. The showerhead assembly 120 may comprise one or more zones, as discussed in FIGS. 4A-4B.

The showerhead assembly 120 comprises a showerhead plate 128, and a heat transfer plate 130 disposed over the showerhead plate 128. A thermal gasket or other thermal interface material (not shown) may be disposed between the showerhead plate 128 and the heat transfer plate 130. The showerhead plate 128 comprises a metal backing plate, such as an aluminum plate, and gas channels 310 disposed within the metal backing plate. The showerhead plate 128 is bonded to a gas distribution plate (GDP) 302, where the GDP 302 is disposed in thermal contact with the showerhead plate 128. The gas channels 310 formed in the showerhead plate 128 are open to the bottom surface of the showerhead plate 128, such that the GDP 302 forms the bottom boundary of each gas path 310, thus eliminating the need to weldingly seal the gas paths as conventionally done while fabricating the showerhead plate 204 of the conventional showerhead assembly 200 illustrated in FIG. 2. One or more screws or bolts 328 are used to connect the metal backing of the showerhead plate 128 to a heat transfer plate 130. Because the bolts 328 are connected to the metal backing of the showerhead plate 128, springs as used in conventional showerhead assemblies 200 are unnecessary, as the bolts 328 are not threaded into the GDP 302. Since the GDP 302 no longer needs to have sufficient thickness to accommodate threaded inserts (or a treaded hole), the GDP 302 is significantly thinner than the conventional GDP 202, thus making the GDP 302 significantly less expensive and easier to fabricate.

The GDP 302 comprises a plurality of holes 360 formed therethrough. Each of the holes 360 has a same size in order to evenly distribute gas within a given zone 342-346 (shown in FIGS. 4A-4B). First ends of the plurality of holes 360 of the GDP 302 are open to the gas channels 310. The gas channels 310 are disposed directly on the GDP 302, and may have a serpentine-like shape, weaving in and out of the metal backing. A gas passageway 314 is coupled to the gas channels 310 to provide gases to the gas channels 310 during operation. The gas channels 310 and the gas passageway 314 are anodized to protect the gas channels 310 and gas passageway 314 from corrosive gases, as shown by the dotted lines 340 in FIG. 3C, as the gas channels 310 and gas passageway 314 are in contact with process gases during operation. The gas channels 310 of the showerhead plate 128 are recessed from the metal backing, like shown in FIGS. 4A-4B. As discussed above, the GDP 302 has a thickness in the y-direction of about 2.5 mm, which is significantly thinner than the conventional GDP 202 of FIG. 2. Due to the thinness of the GDP 302, the plurality of holes 360 in the GDP 302 may be mechanically drilled or laser drilled. Mechanically drilling the plurality of holes 360 is less expensive than laser drilling. Moreover, as the GDP 302 is much thinner, the holes 360 can be formed more rapidly, with less damage, thus further saving time and fabrication costs as compared to fabricating the much thicker, conventional GDP 202.

The heat transfer plate 130 comprises cooling channels 318 disposed on a first side 321 of the showerhead assembly 120, and a cap 319 is disposed between the first side 321 and the cooling channels 318. The cooling channels 318 are grooves or slots disposed within the heat transfer plate 130 that have a cap 321 welded over the cooling channels 318 to allow a coolant or other heat transfer fluid to flow therethrough. The heat transfer plate 130 comprises a first side 322 and a second side 324 disposed opposite the first side 322. The first side 322 has a larger outer diameter than the outer diameter of the second side 324. One or more heaters 316 are disposed in one or more heater receiving channels 317 disposed on the second side 324 of the heat transfer plate 130. The one or more heaters 316 are sealed in the heater receiving channels 317 with one or more plugs 323, where the one or more plugs 323 are welded to the heat transfer plate 130.

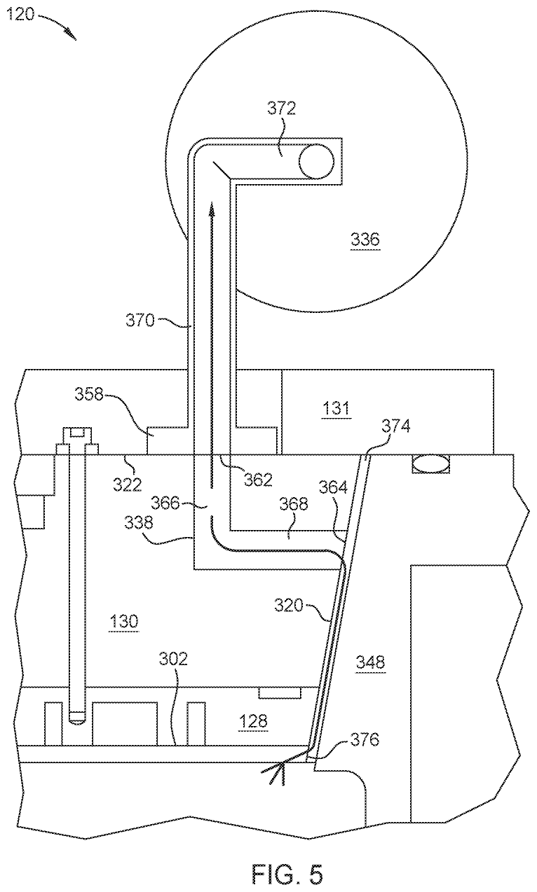

The first and second sides 322, 324 are coupled together by a tapered sidewall 320, where the tapered sidewall 320 extends from the first surface 322 near the lid 131 to the showerhead plate 128 (i.e., the tapered sidewall 320 is tapered from the first surface 322 to the second surface 324 in the -y direction). The tapered sidewall 320 of the heat transfer plate 130 is disposed to a tapered sidewall 332 of the showerhead plate 128. The tapered sidewall 332 of the showerhead plate 128 extends from the second side 324 of the heat transfer plate 130 to a bottom surface 333 of the showerhead plate 128. A pressure sensor 336 is disposed over the lid 131, and a pressure sensing channel 338 runs down the sidewall 320, like shown in FIG. 5.

As shown in FIG. 3B, the GDP 302 is bonded to the bottom surface 333 of the showerhead plate 128 with a thermally and electrically conductive adhesive 326. The bottom surface 333 is bare, non-anodized metal so that an electrical connection can be made through the adhesive 326. The adhesive 326 maintains a ground path between the GDP 302 and the heat transfer plate 130. A portion of the adhesive 326 disposed on the GDP 302 extends over the anodized gas channels 310 to ensure the bare metal bottom surface 333 of the showerhead plate 128 is protect from the gases flowing through the paths 310. The adhesive 326 is silicon based and comprises carbon and aluminum. The adhesive 326 may have a thickness of about 0.1 mm to about 0.2 mm.

Because the showerhead plate 128 and the GDP 302 are coupled together by the adhesive 326 and are distinct from the heat transfer plate 130 (i.e., not embedded within the heat transfer plate 130, unlike a conventional showerhead assembly), the showerhead plate 128 and the GDP 302 can be easily replaced when needed.

FIG. 4A illustrates a bottom view of the showerhead plate 128 of the showerhead assembly 120 of FIGS. 3A-3C that includes two or more gas delivery zones, according to one embodiment. FIG. 4B illustrates a bottom view of the showerhead plate 128 of the showerhead assembly 120 comprising three or more zones, according to another embodiment.

As shown in FIG. 4A, the showerhead assembly 120 includes at least an outer zone 342 and an inner zone 344. Both the outer and inner zones 342, 344 comprise individual (e.g., separate) plenums connected to separate gas passageways 314. The outer and inner zones 342, 344 are fluidly isolated and separated by a ring formed from the adhesive 326 coupling the GDP 302 to the showerhead plate 128, thus enabling the amount and/or type of gas delivered to each zone 342, 344 to be separately controlled. Similarly, as shown in FIG. 4B, the showerhead assembly 120 may comprise the outer zone 342, an inner zone 344, and a center zone 346 separated by a ring formed from the adhesive 326 coupling the GDP 302 to the showerhead plate 128. In the showerhead assembly 120 of FIG. 4B, the center zone 346 is extremely small, resulting in the gas flow to the center zone 346 being highly controllable. In the example depicted in FIG. 4B, each of the zones 342-346 are concentric to a centerline of the showerhead assembly 120.

In FIGS. 4A and 4B, the curved rectangular portions 352 illustrate raised mesas form on the bottom surface 333 of the showerhead plate 128, and the recessed portions 354 defined between the curved rectangular portions 352. The recessed portions 354 define the portion of the anodized gas channels 310 formed in the bottom surface 333 of the showerhead plate 128. As such, the recessed portions 354 are anodized while the raised curved rectangular portions 352 are not (i.e., are bare aluminum). The adhesive 326 coupling the GDP 302 to the showerhead plate 128 is disposed on the bare raised curved rectangular portions 352 to provide good electrical conduction between the showerhead plate 128 and the GDP 302. The plurality of holes 360 of the GDP 302 align with the recessed portions 354.

FIG. 5 illustrates a pressure sensor 336 and a pressure sensing channel 338 of the showerhead assembly 120 of FIGS. 3A-3C, according to one embodiment. As shown, a pressure sensing channel 338 is formed through the heat transfer plate 130. The pressure sensing channel 338 extends between a top port 362 formed in the top surface 322 of the heat transfer plate 130 and a side port 364 formed in the sidewall 320 of the heat transfer plate 130. The pressure sensing channel 338 may be a straight hole extending between the ports 362, 364, or have multiple connected sections. For example, in the embodiment depicted in FIG. 5, the pressure sensing channel 338 includes a first section 366 extending form the top port 362 to a second section 368. The second section 368 extends from the first section 362 to the side port 364. In one example, the first section 366 has a centerline that is parallel to a centerline of the showerhead assembly 120 and/or the heat transfer plate 130, while the second section 368 has a centerline that is perpendicular to the centerline of the first section 366. The centerlines of one or both of the first and second sections 366, 368 may have other orientation, or be combined with additional sections. As discussed above, the interior surfaces of the pressure sensing channel 338 are anodized to provide protection from process and other gases.

An adapter 358 disposed on the first surface 322 of the heat transfer plate 130 is coupled to the pressure sensor 336 via a conduit 370. The pressure sensing channel 338 is coupled to the adapter 358 and has a first end 372 at the top of the conduit 370 near the pressure sensor 336. The pressure sensing channel 338 runs down the sidewall 320 in a gap 374 formed between the heat transfer plate 130 and the isolator 122 or liner 348, before continuing between the GDP 302 and a liner 348 of the showerhead assembly 120 to a second end 376 of the pressure sensing channel 338. The second end 376 of the pressure sensing channel 338 is in fluid communication with the gap 374 to allow pressure to be read of the process region 112 by the pressure sensor 336 without having a port exposed on the bottom surface of GDP 302 and/or the showerhead plate 128. The pressure of the gap 374 of the pressure sensing channel 338 is the same as the pressure of the processing chamber with a marginal time delay (i.e., less than one second), and thus, results in a substantially real-time response of the pressure of the chamber. While the first and second sections 366, 368 of the pressure sensing channel 338 are shown as being L-shaped, the pressure sensing channel 338 may be drilled from the adapter 358 to the sidewall 320 at an angle (e.g., as one diagonal section).

In conventional showerhead assemblies, the pressure sensing channel extends from an upper port to a lower port, where the lower port faces a substrate within the processing chamber. Since the pressure sensing channel 338 of the showerhead assembly 120 does not require a lower port facing a substrate, the processing chamber has an overall thermal and processing uniformity. Furthermore, the pressure sensing channel 338 lacking a lower port prevents the pressure sensing channel 338 from being exposed to a plasma or gas during operation, as a lower port can cause non-uniformity in processing a substrate.

Therefore, due to the showerhead plate 128 and the GDP 302 being coupled together by the adhesive and being distinct from the heat transfer plate 130 (i.e., not embedded within the heat transfer plate 130 like a conventional showerhead assembly), the showerhead plate 128 and the GDP 302 can be easily replaced when needed. Moreover, the showerhead plate 128 can be anodized, and the thin GDP 302 may have mechanically drilled holes, thus resulting in reduced costs when compared to a conventional showerhead assembly.

While the foregoing is directed to embodiments of the present disclosure, other and further embodiments of the disclosure may be devised without departing from the basic scope thereof, and the scope thereof is determined by the claims that follow.

What is claimed is:

1. A showerhead assembly, comprising:
a heat transfer plate having a first side coupled to a second side by a sidewall, the heat transfer plate having cooling channels formed adjacent the first side of the heat transfer plate and a heater disposed in a heater receiving channel formed in the second side of the heat transfer plate;
a showerhead plate having a first side coupled to the second side of the heat transfer plate; and
a gas distribution plate bonded to a second side of the showerhead plate, the gas distribution plate having a first plurality of holes formed therethrough, first ends of the first plurality of holes open to the showerhead plate.

2. The showerhead assembly of claim 1, wherein the showerhead plate comprises a plurality of gas channels formed in a bottom surface of the showerhead plate, the plurality of gas channels being bounded on one side by the gas distribution plate.

3. The showerhead assembly of claim 2, wherein the plurality of gas channels are anodized.

4. The showerhead assembly of claim 2, wherein the showerhead plate is bonded to the gas distribution plate using an adhesive, the adhesive comprising Si, Al, and C.

5. The showerhead assembly of claim 1, further comprising a first gas passageway extending through the heat transfer plate and fluidly coupled to the plurality of gas channels formed in the showerhead plate.

6. The showerhead assembly of claim 1, wherein the first plurality of holes are formed in a first zone of the gas distribution plate, and wherein the gas distribution plate further comprises a second zone having a second plurality of holes formed therethrough, first ends of the second plurality of holes being open to the to the showerhead plate.

7. The showerhead assembly of claim 6, wherein the gas distribution plate further comprises a third zone having a third plurality of holes formed therethrough, first ends of the third plurality of holes being open to the to the showerhead plate.

8. The showerhead assembly of claim 1, further comprising a pressure measurement path formed through the heat transfer plate, the pressure measurement path having a first end formed in the first side of the heat transfer plate and a second end formed in the sidewall.

9. A showerhead assembly, comprising:
a heat transfer plate having a first side coupled to a second side by a sidewall, the heat transfer plate having cooling channels formed adjacent the first side of the heat transfer plate and a heater disposed in a heater receiving channel formed in the second side of the heat transfer plate;
a showerhead plate having a first side coupled to the second side the heat transfer plate, wherein the showerhead plate comprises a plurality of anodized gas channels in a second side of the showerhead plate;
a first gas passageway extending through the heat transfer plate to the plurality of anodized gas channels of the showerhead plate; and
a gas distribution plate bonded to a second side of the showerhead plate, the gas distribution plate having a first plurality of holes formed therethrough, first ends of the first plurality of holes open to the plurality of anodized gas channels formed in the showerhead plate.

10. The showerhead assembly of claim 9, wherein the plurality of anodized gas channels of the showerhead plate are partially bounded by the gas distribution plate.

11. The showerhead assembly of claim 9, wherein the showerhead plate is bonded to the gas distribution plate using a thermally and electrically conductive adhesive, the thermally and electrically conductive adhesive comprising Si, Al, and C.

12. The showerhead assembly of claim 9, wherein the first plurality of holes are formed in a first zone of the gas distribution plate, and wherein the gas distribution plate further comprises a second zone having a second plurality of holes formed therethrough, first ends of the second plurality of holes being open to the showerhead plate.

13. The showerhead assembly of claim 12, wherein the gas distribution plate further comprises a third zone having a third plurality of holes formed therethrough, first ends of the third plurality of holes being open to the showerhead plate.

14. The showerhead assembly of claim 9, further comprising a pressure sensing channel formed through the heat transfer plate, the pressure sensing channel having a first port formed in the first side of the heat transfer plate and a second port formed in the sidewall.

15. A processing chamber comprising:
a chamber body having an internal volume;
a substrate support disposed in the internal volume;
a lid disposed on the chamber body and enclosing the internal volume;
a heat transfer plate having a first side coupled to a second side by a sidewall, the heat transfer plate having cooling channels formed adjacent the first side of the heat transfer plate and a heater disposed in a heater receiving channel formed in the second side of the heat transfer plate;
a showerhead plate having a first side coupled to the second side the heat transfer plate, wherein the showerhead plate comprises a plurality of gas channels in a second side of the showerhead plate; and
a gas distribution plate bonded to a second side of the showerhead plate, the gas distribution plate having a first plurality of holes formed therethrough, first ends of the first plurality of holes open to the plurality of gas channels formed in the showerhead plate.

16. The showerhead assembly of claim 15, further comprising a first gas passageway extending through the heat transfer plate to the showerhead plate, wherein the first gas passageway and the plurality of gas channels are anodized.

17. The showerhead assembly of claim 15, wherein the showerhead plate is bonded to the gas distribution plate using an adhesive, the adhesive comprising Si, Al, and C.

18. The showerhead assembly of claim 15, wherein the first plurality of holes are formed in a first zone of the gas distribution plate, and wherein the gas distribution plate further comprises a second zone having a second plurality of holes formed therethrough, first ends of the second plurality of holes being open to the showerhead plate.

19. The showerhead assembly of claim 18, wherein the gas distribution plate further comprises a third zone having a third plurality of holes formed therethrough, first ends of the third plurality of holes being open to the showerhead plate.

20. The showerhead assembly of claim 15, further comprising a pressure measurement path formed through the heat transfer plate, the pressure measurement path having a first end formed in the first side of the heat transfer plate and a second end formed in the sidewall.
